(19) United States
(12) Patent Application Publication
(10) Pub. No.: US 2012/0121870 A1
(43) Pub. Date: May 17, 2012

(54) Multilayer structure comprising a precious metal stuck onto a dielectric substrate, and an associated method and use

(75) Inventors: Timothee TOURY, Prugny (FR); Marc LAMY DE LA CHAPELLE, Fontenay Sous Bois (FR); Hong SHEN, Troyes Cedex (FR); Bruno GUELORGET, Bucheres (FR)

(73) Assignee: UNIVERSITE DE TECHNOLOGIE DE TROYES, Troyes (FR)

(21) Appl. No.: 13/272,000

(22) Filed: Oct. 12, 2011

(30) Foreign Application Priority Data
Oct. 12, 2010 (FR) 1058263

(51) Int. Cl. B32B 15/02; B32B 9/04; C23C 16/04; B32B 15/04; B32B 3/10; B82Y 30/00

(52) U.S. Cl. 428/201; 428/447; 428/429; 428/208; 428/221; 427/259; 977/810

(57) ABSTRACT

The invention provides a multilayer structure comprising a dielectric substrate; a sticking layer that extends over a first face of the dielectric substrate; at least one layer of precious metal placed on the sticking layer, said sticking layer comprising a derivative of an alkylsilane, the layer of precious metal being applied by evaporation or by sputtering said precious metal.

The invention also provides a method of fabricating said device based either on electron beam lithography, optical lithography or nanoimprint lithography.

### TECHNICAL FIELD OF THE INVENTION

The invention relates to the field of plasmonics, more precisely to multilayer structures such as glass plates on which precious metal nanoparticles are stuck or deposited. Such devices are used in particular as sensors for chemical or biological species. The invention also relates to methods of fabricating such devices based essentially on nanolithography.

To date, many methods of fabricating multilayer structures including a precious metal layer have been proposed. Such methods and devices are not satisfactory, however.

### PRIOR ART

US 2008/160287 discloses a structure comprising a glass substrate on which elongate metallic nanoparticles are disposed along the substrate at a constant interval without a sticking layer. That metallic structure, however, is not satisfactory for gold nanoparticles, since such nanoparticles do not adhere to glass in satisfactory manner.

The patent application mentioned above also discloses a method of fabrication in which a sticking layer of chromium is inserted between the glass substrate and the nanoparticles. That structure has been found not to be sufficiently advantageous, since the optical properties of that type of structure are altered: this can be explained in particular by a very strong absorption of the multilayer structure due to the presence of the layer of chromium that imparts a very high index and attenuates plasmon resonance.

### SUMMARY OF THE INVENTION

The aim of the invention is to overcome the disadvantages of the prior art and in particular to propose a multilayer structure having both mechanical and optical properties that are improved relative to the prior art.

To this end, a multilayer structure is provided, comprising a dielectric substrate; a sticking layer that extends over a first face of the dielectric substrate; and at least one layer of precious metal placed on the sticking layer, said sticking layer comprising a derivative of an alkylsilane compound with formula (I):

(RO)ₐ—Si—((CH₂)_{c}—(XHₑ))_{b} (I)

in which R is CH₃, C₂H₅ or C₃H₇, a is 2 or 3, b is 4−a, c is 1 to 6, e is 1 or 2 and X is S or N.

In a first aspect, the layer of precious metal is applied by evaporation or by sputtering said precious metal.

Preferably, the dielectric substrate essentially comprises glass.

Evaporating the layer of precious metal enables a multilayer structure to be obtained comprising a layer of precious metal that preferably measures 1 nm to 100 nm in thickness.

The term “multilayer structure” means a set of layers associated with at least one face of a dielectric substrate. The multilayer structure obtained has improved mechanical and/or optical properties compared with a base dielectric substrate. An example of a multilayer structure is a glass plate covered with nanoparticles of gold. That type of device is employed in particular to carry out analyses of chemical or biological extracts by an optical method.

The term “dielectric substrate” means any solid material that is transparent or opaque to visible light, ultraviolet light or infrared light. Said material advantageously comprises silicon atoms or silicon oxide groups. In general, the dielectric substrate may consist of a mineral glass (soda-lime-silica, borosilicate, vitroceramic, etc.) or an organic glass (thermoplastic polymer such as polyurethane or a polycarbonate) or any other dielectric material.

The term “alkylsilane compound” means an organic molecule comprising alkyl groups with at least one carbon atom grafted either directly or via an oxygen or nitrogen atom to a silicon atom. The alkylsilane compound may be in the form of a “derivative”, i.e. it loses certain chemical groups when it forms part of the composition of the multilayer structure.

In interpreting the present invention, the expression “precious metal” is taken to mean any type of metal that can bond covalently to a thiol or amino function of a mercaptoalkyl or aminoalkyl group. This expression designates platinum, palladium, gold, silver, copper, or aluminum, for example.

Advantageously, one and/or the other of the sticking layer and the layer of precious metal extend(s) over all or a portion of the first face of the dielectric substrate.

In accordance with another aspect of the multilayer structure of the invention, the layer of precious metal is constituted by nanoparticles that have a predetermined shape and/or arrangement and/or orientation. As an example, the nanoparticles may represent a determined pattern that may be regular or irregular.

The precious metal layer may also be constituted by a film stuck over the whole of the dielectric substrate surface.

The term “nanoparticles” of a metal means structures essentially composed of metal and preferably measuring between one nanometer and several hundred micrometers. The dimensions of the precious metal layer are fixed by the choice of the dielectric substrate and by the conditions for evaporation or by sputtering of the precious metal employed during fabrication of the multilayer structure.

Advantageously, the alkylsilane compound is 3-mercaptopropyl-trimethoxysilane (below denoted as MPTMS).

Preferably, the precious metal of the multilayer structure is gold or silver.

The invention also provides a method of fabricating a multilayer structure as mentioned above, comprising a step for depositing a layer of protective resin over at least a first face of the dielectric substrate, a step for lithography, carried out on the layer of protective resin at specified zones of the resin, a first step for removing said layer of protective resin at the specified zones of the resin, a step for metallization in order to stick said precious metal layer to said sticking layer in the specified zones of the resin, and a second step for removing the layer of protective resin, the method further comprising a step for silanization in order to stick in the sticking layer, carried out either before the step for depositing a layer of protective resin or between the first step for removing the layer of protective resin and the step for metallization.

Preferably, the step for metallization is carried out by evaporation or by sputtering a precious metal over said sticking layer.

The step for lithography may be carried out in different manners to depolymerize the resin in specified zones of the resin and throughout the thickness of the layer of resin. Each of these methods requires a type of resin and steps for removing the resin that are suitable for the method that is carried out.

Advantageously, the step for lithography comprises one or more lithography(ies) selected from the group comprising nanoimprint lithography, ion beam lithography, electron beam lithography and optical lithography using infrared, visible, or ultraviolet radiation.

In accordance with a preferred implementation, the method of the invention further comprises: a step for depositing a conductive layer carried out after the step for depositing a layer of protective resin and before the step for lithography; and a step for removing said conductive layer carried out after the step for lithography and before the first step for removing the protective resin layer at specified zones of the resin; and the step for lithography comprises electron beam lithography and acts on the protective layer of resin via the conductive layer.

The invention also provides the use of a multilayer structure as described above in an optical analysis apparatus.

### BRIEF DESCRIPTION OF THE FIGURES

Other characteristics, details, and advantages of the invention become apparent from the following description made with reference to the accompanying drawings in which:

FIG. 1A is a diagram of the method in accordance with an embodiment of the invention based on electron beam lithography;

FIG. 1B is a diagram of the multilayer structure obtained by the method of FIG. 1A;

FIG. 2 illustrates extinction spectra for two samples comprising a layer of gold nanoparticles and a sticking layer composed respectively of MPTMS and of chromium;

FIG. 3 shows surface-enhanced Raman spectra of the samples of FIG. 2;

FIG. 4A is a top view of a sample with a multilayer structure comprising six lines of gold nanoparticles adhered without a sticking layer;

FIG. 4B shows the sample of FIG. 4A after a scratch test;

FIG. 5 shows a top view, following a scratch test, of a sample with a multilayer structure comprising four lines of gold nanoparticles adhered with a sticking layer of MPTMS;

FIG. 6 shows a top view, following a scratch test, of a multilayer structure sample comprising four lines of gold nanoparticles adhered with a chromium sticking layer;

FIG. 7 is a diagram of surface topographies measured during a scratch test carried out on the sample of FIGS. 4A and 4B;

FIG. 8 is a diagram of surface topographies measured during a scratch test carried out on the sample of FIG. 5; and

FIG. 9 is a diagram of surface topographies measured during a scratch test carried out on the sample of FIG. 6.

For clarity, identical or similar elements are given identical references throughout the figures.

### DETAILED DESCRIPTION OF AN EMBODIMENT

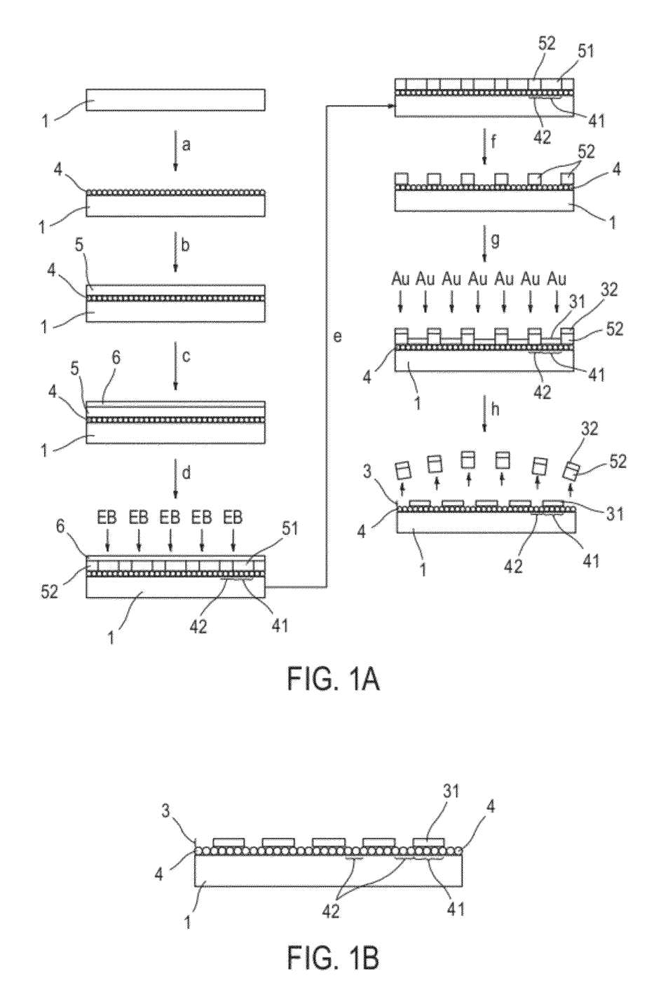

As can be seen in FIG. 1A, the method in accordance with a preferred embodiment of the invention preferably commences with a step for silanization, -a-, which is intended to apply a sticking layer 4 of an alkylsilane derivative such as MPTMS onto a dielectric substrate 1 such as a glass plate.

Silanization is known per se and has, for example, been described by Charles A. Goss et al, Anal. Chem, 63, 85 (1991).

Silanization commences with immersing glass plates 1 for 30 minutes in a freshly prepared piranha solution. Piranha solution is a mixture of one volume of 30% hydrogen peroxide solution with three volumes of 98% sulfuric acid solution. The glass plates are then rinsed with distilled water, dried in a stream of nitrogen, then placed on a hot plate at 100° C. for approximately 10 minutes. After these steps, according to the literature, it is assumed that the glass surfaces will exhibit hydroxyl groups (—Si—OH). The pre-treated glass plates are then immersed in a silanization solution heated to boiling point for ten minutes; next, they are rinsed with sufficient 2-propanol and dried in a stream of nitrogen; the glass plates are then heated to 105° C. for 10 minutes. The above steps carried out on the pre-treated plates are repeated three times to obtain a sticking layer 4 composed of MPTMS. It is probable that during these steps, certain alkoxy groups of the MPTMS have dissociated so as to allow covalent Si—O bonds to be produced between the silicon atoms of the MPTMS and the hydroxyl groups of the glass plate 1.

The step for silanization -a- is followed by a step -b- for depositing a layer of electrosensitive resin 5 on the sticking layer 4. Deposition may be carried out by spin coating. The resin is sensitive to electrons, and so electron lithography can be carried out. The resin selected is preferably a polymethylmethacrylate (PMMA) resin, but other resins that are known to the skilled person, such as a SU-8 resin, may be used without departing from the scope of the invention. The multilayer structure obtained is then pre-cured.

The next step is a step -c- for depositing a conductive layer 6, constituted by aluminum, for example, over the protective resin 5. This step is carried out by evaporating aluminum onto the resin layer 4. The aluminum layer 6 promotes electron lithography, since glass is not an electrical conductor. The aluminum layer obtained is approximately 10 nm thick.

The next step, -d-, consists in exposing the aluminum layer to an electron beam EB (when using electron beam lithography). During this step for lithography, the electron beam is advantageously focused on specified zones of the aluminum layer 6 such that the set of said specified zones defines a drawing, or a specified pattern. The electron beam EB is thus indirectly focused on specified zones of resin 51 of the layer of PMMA 5 so as to subsequently enable adhesion of precious metal structures 31 to said specified resin zones 51, as is explained below. The precious metal structures 31 that are thus stuck in will define the same specified pattern. The portions or zones of the resin 5 onto which the electron beam is not focused are given reference numeral 52.

The method is then continued with a step -e- for removing the conductive layer 6. With an aluminum conductive layer, this step consists in immersing the multilayer structure in potassium hydroxide (KOH). Next, a development step, -f-, is carried out, for example by immersion in a mixture of methyl-isobutyl-ketone and isopropanol (known as a MIBK: IPA solution). That solution is an organic solvent that is known to the skilled person. Step -f- can be used to eliminate the specified zones of resin 51 located facing the specified zones of MPTMS 41 onto which the electron beam EB has been focused. The specified zones of resin 52 remain attached to the multilayer structure facing the specified zones 42 of MPTMS.

The next step is a step -g- for metallization by evaporating a precious metal such as gold, —Au—, onto the sticking layer 4 and onto the specified zones of resin 52. This step results in the formation of a thin layer of gold on the sticking layer 4 and on the specified zones of resin 52. The layers of gold that are thus stuck onto a glass plate have good adhesive properties compared with prior art multilayer structures. It is probable that during this step, gold atoms are stuck onto the sticking layer 4 by means of covalent Au—S bonds formed between the gold nanoparticles and thiol functions of the MPTMS, i.e. bonds are formed between the gold atoms and the sulfur atoms of the MPTMS.

The method is then continued by a detachment step, -h-, carried out, for example, by immersing the multilayer structure in a solution of acetone. After this step, the specified zones of resin 52 and the layer of gold 32 adhered to these specified zones of resin 52 are detached from the multilayer structure.

Thus, at the end of this method, a multilayer structure as shown in FIG. 1B is obtained, comprising a layer of glass 1, a sticking layer 4 of MPTMS that extends over the entire surface of the glass, and a layer of precious metal 31 that adheres to the sticking layer 4 in accordance with a specified pattern selected by the user as a function of the desired application.

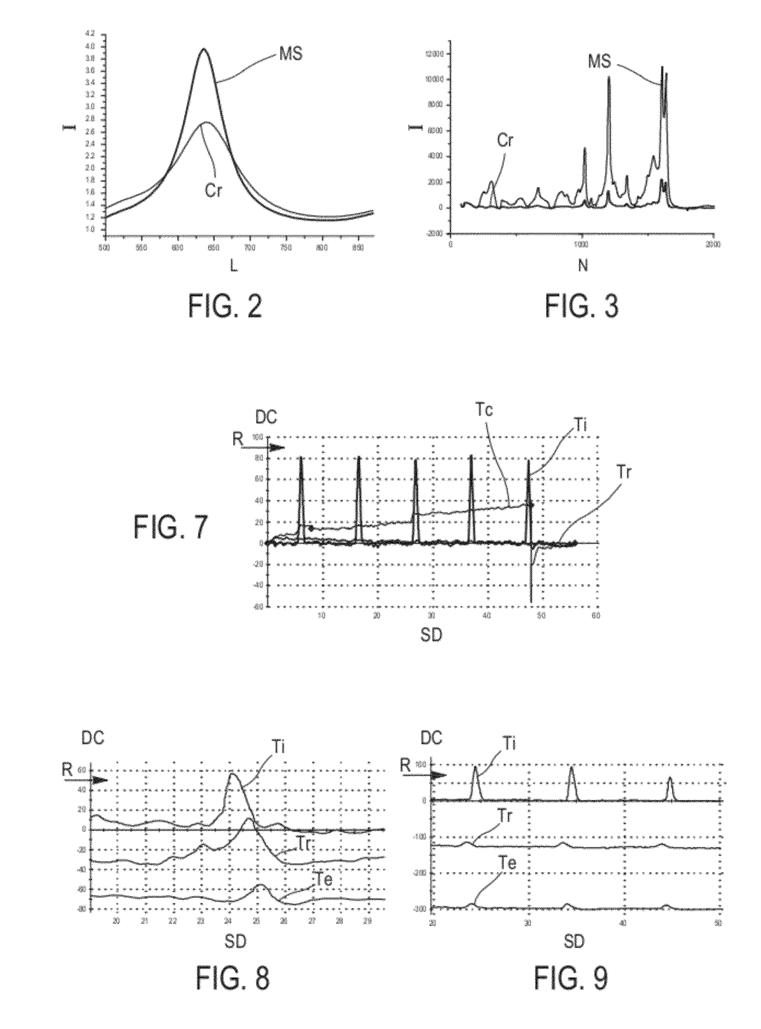

Referring now to FIG. 2, plasmon resonance measurements were carried out on two multilayer structures comprising a layer of gold nanoparticles and respectively a sticking layer of MPTMS and of chromium. FIG. 2 represents a graph of the change in intensity I of the resonance in arbitrary units (up the ordinate) as a function of wavelength L in nanometers (along the abscissa). The curve MS corresponds to the measurements made on the structure comprising a layer of MPTMS; and the curve Cr, the curve comprising a layer of chromium. The curve MS has higher intensity at wavelengths in the range 575 nm to 675 nm. It can clearly be seen that the layer of MPTMS provides the multilayer structure with improved optical properties compared with the layer of chromium. In fact, the resonance is narrower (by approximately 25%) and more intense when a layer of MPTMS is used, irrespective of the size of the nanoparticles employed. The resonance quality factor is thus improved using such a layer.

Referring now to FIG. 3, BPE-enhanced Raman spectra were produced for the two multilayer structures comprising a layer of gold nanoparticles in the form of 130 nm diameter cylinders and a sticking layer of MPTMS and of chromium respectively. The ordinate is a scale of intensities I (in arbitrary units) and the abscissa is the wave number N scale (in cm⁻¹). The spectrum MS corresponds to a MPTMS sticking layer, while the spectrum Cr corresponds to a chromium sticking layer. The improvement in the optical properties mentioned above induces an augmentation in the enhancement factors of the Raman signal obtained with the nanoparticles on a MPTMS sticking layer 4. The additional enhancement factor is of the order of 10, i.e. one order of magnitude, between the use of chromium and of MPTMS.

This augmentation of the signal when using MPTMS as a sticking layer has proved to be highly satisfactory, especially when using said substrates as sensors for chemical or biological species. In fact, the greater the enhancement, the lower the detection limit, which means that the sensitivity of the sensor is higher.

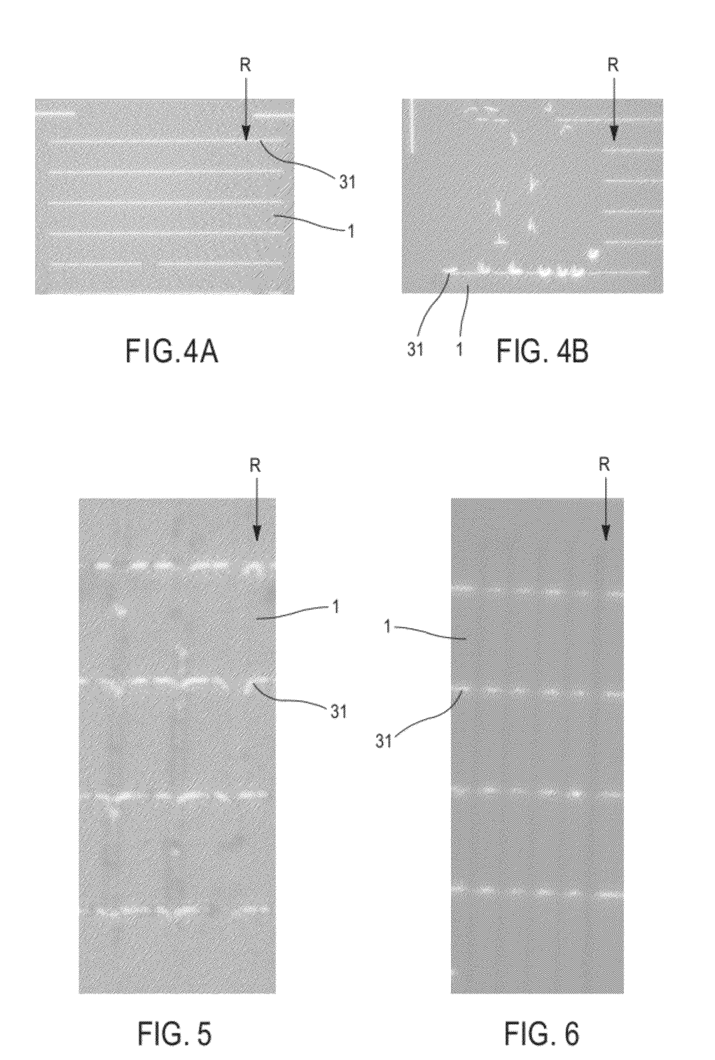

Referring now to FIG. 4A, a first sample was produced from a glass plate 1 onto which nanoparticles of gold that were 5 μm long, 200 nm wide and approximately 80 nm high had been adhered without a sticking layer. These nanoparticles were initially aligned so as to form six lines of gold 31 on the glass plate 1.

The first sample underwent a scratch test. This test consisted in bringing a tip such as a pyramidal diamond tip into contact with the surface of the test sample bearing the lines of gold 31. An adjustable load was applied to said surface, then the sample (or the tip) was moved in order to generate scratches. Reference R illustrates the direction of the scratches made in the scratch test.

The scratch test was carried out in three stages. FIG. 7 illustrates the result of these steps, as is explained below. Firstly, the tip measured the initial topography Ti of the surface by being moved over the sample in the direction of the arrow R under a very small load (i.e. a force of the order of 5 μN in a direction perpendicular to the plane of the sample and oriented towards it); next, after returning it to its starting point, the tip produced the scratch per se, under a constant load (topography Tc); finally, the tip retraced its path under a low load in order to measure the residual topography Tr.

Thus, the first sample was scratched perpendicular to the lines of gold. Each scratch was produced under a constant load, but different loads were applied in order to determine the critical load, i.e. that which could detach the gold from the glass.

Referring now to FIG. 4B, at the end of the scratch test on the sample 1, the gold nanoparticles that were insufficiently stuck had been moved and piled up at one end of the glass plate in the region of the last line of gold. This type of pile of nanoparticles 31 is what can be seen at the bottom of FIG. 4B.

Referring now to FIG. 5, a similar sample to the preceding sample but with a sticking layer of MPTMS also underwent a scratch test. The scratch was made under a constant load corresponding to approximately 400 μN. It can be seen that certain lines of gold have been broken, others have been slightly offset or deformed, but the phenomenon of detachment of the whole line during movement of the tip no longer occurs, nor of piling up of the nanoparticles at the end of the path, as with FIG. 4B when the gold was adhered directly to the glass (i.e. with no sticking layer).

FIG. 5 additionally shows that the gold is not completely torn off by the diamond tip. This experiment leads to the conclusion that the critical load with this sample is approximately 400 μN.

Referring now to FIG. 6, another sample similar to the above but with a sticking layer of chromium also underwent a scratch test. The scratch was produced with a constant load of 6 mN. It can be seen that the gold had been torn off only in the path of the tip. Adhesion of the gold in this sample was comparable to that of the sample comprising a layer of MPTMS. This experiment leads to the conclusion that the critical load with this sample is approximately 6 mN.

Referring now to FIG. 7, movement of the tip over the multilayer structure is recorded during the scratch test carried out on the sample of FIGS. 4A and 4B. The ordinate shows a scale of movement (DC) in nanometers; the abscissa is a scale of scratch distance (SD) in μm. The initial topography measurement Ti shows that the tip has encountered five structures approximately 80 nm in height. The scratch made with a force of 10 μN has detached the gold structures that have piled up around the tip, resulting in a topography Tc generally formed like steps. The final topography is almost zero, since the 10 μN scratch has removed almost everything. The critical load for the gold on glass sample is thus in the range 5 μN to 10 μN. This therefore points to the well-known result, namely that adhesion of gold to glass is very weak.

FIG. 8 represents the topography measurement on the third line of gold of the sample of FIG. 5. The initial topography Ti shows that the third line of gold measures approximately 60 nm in height. The scratches in the direction of the arrow R at 400 μN have deformed the glass plate such that the measurement of the intermediate topography Tc is offset to a lower ordinate. During the measurement of the final topography, the glass has partially regained its initial shape so that the measurement of the residual topography Tr is also offset, but is substantially identical to the measurement of the initial topography Ti. This scratch test clearly confirms that the gold is not completely torn off from a multilayer structure comprising a layer of MPTMS.

FIG. 9 represents the topography measurements for the last three lines of gold of the sample of FIG. 6 wherein the sticking layer 4 is formed from chromium. The topography measurements Ti, Tc and Tr are offset in the same manner as for those of FIG. 8. This scratch test clearly confirms that the gold is not completely torn off from a multilayer structure comprising a layer of chromium as the sticking layer. Although the gold is almost no longer visible on the path of the tip at 6 mN, the lines are still detected in the final topography (curve Tr). Other tests were carried out, at 10 mN and 15 mN. It was more difficult with these to precisely discern the remainders of the lines of gold (approximately 10 nm residual for the 10 mN load), because the tip scratched more and more deeply into the glass, but the gold was only scratched off in the path of the tip. It can be deduced therefrom that in the presence of a sticking sub-layer of chromium, the critical load is close to 6 mN. Because of the respective critical loads, adhesion with a sticking layer of chromium appears to be better than with a sticking layer of MPTMS.

A plurality of combinations may be envisaged without departing from the scope of the invention; in particular, the skilled person will adapt the method of the invention to the lithography technique employed.

1. A multilayer structure comprising:
a dielectric substrate;
a sticking layer that extends over a first face of the dielectric substrate;
at least one layer of precious metal placed on the sticking layer, said sticking layer comprising a derivative of an alkylsilane compound with formula (I):
(RO)ₐ—Si—((CH₂)_{c}—(XHₑ))_{b} (I)
in which R is CH₃, C₂H₅ or C₃H₇, a is 2 or 3, b is 4−a, c is 1 to 6, e is 1 or 2 and X is S or N, the layer of precious metal being applied by evaporation or by sputtering said precious metal as a metallization g);
wherein the layer of precious metal consists in nanoparticles that have a predetermined shape and/or arrangement and/or orientation.

2. The multilayer structure according to claim 1, wherein the dielectric substrate essentially comprises glass.

3. The multilayer structure according to claim 1, wherein one and/or the other of the sticking layer and the layer of precious metal extend(s) over all or a portion of the first face of the dielectric substrate.

4. The multilayer structure according to claim 1, wherein the layer of precious metal is constituted by nanoparticles that represent a pattern or a drawing.

5. The multilayer structure according to claim 1, wherein said alkylsilane compound is 3-mercaptopropyltrimethoxysilane.

6. The multilayer structure according to claim 1, wherein said precious metal is gold or silver.

7. A method of fabricating a multilayer structure according to claim 1, comprising:
b) a step for depositing a layer of protective resin over at least a first face of the dielectric substrate;
d) a step for lithography, carried out on the layer of protective resin at specified zones of the resin;
f) a first step for removing said layer of protective resin at the specified zones of the resin;
g) a step for metallization in order to stick said precious metal layer to said sticking layer in the specified zones of the resin;
h) a second step for removing the layer of protective resin;
wherein the method further comprising a step a) for silanization in order to stick in the sticking layer, carried out either before the step b) for depositing a layer of protective resin or between the first step f) for removing the layer of protective resin and the step for metallization g).

8. The method according to claim 7, wherein the step for metallization g) is carried out by evaporation of or by sputtering a precious metal onto said sticking layer.

9. The method according to claim 7, wherein the step for lithography (d) comprises one or more lithography(ies) selected from the group comprising nanoimprint lithography, ion beam lithography, electron beam lithography and optical lithography using infrared, visible, or ultraviolet radiation.

10. The method according to claim 7, wherein it further comprises:
a step c) for depositing a conductive layer carried out after the step b) for depositing a layer of protective resin and before the step for lithography d); and
a step e) for removing said conductive layer carried out after the step for lithography d) and before the first step f) for removing the protective resin layer at the specified zones of the resin, and the step for lithography d) comprising electron beam (EB) lithography and acting on the protective layer of resin via the conductive layer.

11. A multilayer structure obtained by a method according to claim 7 for use in an optical analysis instrument.
